(19) United States
(12) Patent Application Publication
(10) Pub. No.: US 2007/0237342 A1
(43) Pub. Date: Oct. 11, 2007

(54) METHOD OF LISTENING TO FREQUENCY SHIFTED SOUND SOURCES

(75) Inventor: Ian Agranat, Concord, MA (US)

Correspondence Address: LOWRIE, LANDO & ANASTASI, RIVERFRONT OFFICE, ONE MAIN STREET, ELEVENTH FLOOR, CAMBRIDGE, MA, 02142, US

(73) Assignee: Wildlife Acoustics, Inc., Concord, MA (US)

(21) Appl. No.: 11/277,988

(22) Filed: Mar. 30, 2006

(51) Int. Cl. H04R 1/40; H03G 5/00

(52) U.S. Cl. 381/97; 381/98

(57) ABSTRACT

A method for listening to and comparing high-frequency sounds such as those produced by birds and insects by people suffering from high-frequency hearing loss, common among the aging population. Live sound is received by a microphone to produce an electrical signal. The signal is then digitized and transformed such that high frequency sounds are shifted to lower frequencies making them easier to hear. Recordings of known sources are also transformed for comparison.

### BACKGROUND OF INVENTION

Most people develop hearing loss particularly at high frequencies as they age. This presents a challenge for wildlife scientists and hobbyists, especially for bird watching because many species of birds sing at high frequencies, and many bird watchers belong to an older demographic. In some cases, individuals learn birdsong when they are younger, and then are no longer able to hear these birds later in life. Other individuals may not begin their interest in watching birds until they can no longer hear many of their songs. Many insects, frogs, and other animals also vocalize at high frequencies.

For example, the Blackpoll Warbler song has a typical range of between 8-10 KHz. At the same time, the average human male at age 55 will lose 30 dB hearing sensitivity at 8 KHz, 22 dB at 4 KHz, and 13 dB at 2 KHz. It would therefore be almost impossible for this person to hear a Blackpoll Warbler, especially in a noisy environment.

Human speech is generally lower pitched than birdsong and has a typical range of between 1-4 KHz.

There are numerous examples of hearing aids in the prior art. However, the primary objective of conventional known hearing aids is to help people hear lower frequency human speech rather than high frequency birds and insects. One approach used in conventional hearing aids is to simply amplify sounds. However, if the high frequency hearing loss is severe, amplification will fail to render high frequency sounds intelligible to the listener, regardless of the level of amplification. Furthermore, the amplification of the ambient background noise becomes intolerable for most people.

Another approach is to transform the sound such that high frequencies are shifted into lower frequencies. This approach enables individuals with high-frequency hearing loss to hear high frequency sounds. However, the resulting shifted sound no longer sounds like the original. If the birdwatcher learned a high-pitched song prior to losing their high frequency hearing, the shifted sound will seem foreign and unidentifiable.

### SUMMARY OF INVENTION

The present invention transforms sound by shifting high frequencies into lower frequencies while also providing the user a means of comparing the transformed sound to known sources. Recordings of known sounds such as the songs of specific bird species associated with or stored in the present invention and can be selected and played back with a similar frequency shifting transformation applied. The user can hear the high-frequency sound produced by both the live and recorded sources because these high-frequency sounds have been shifted into frequencies more easily heard by the user. At the same time, the user can compare these two sounds in meaningful ways because they have been subject to a similar transformation.

### BRIEF DESCRIPTION OF DRAWINGS

The accompanying drawings, are not intended to be drawn to scale. In the drawings, each identical or nearly identical component that is illustrated in various figures is represented by a like numeral. For purposes of clarity, not every component may be labeled in every drawing. In the drawings:

FIG. 1 is a general block diagram of a device according to aspects of an embodiment of the invention; and

FIG. 2 is a block diagram showing in detail the Frequency Shifter block of FIG. 1, according to a more particular embodiment of the invention.

### DETAILED DESCRIPTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing”, “involving”, and variations thereof herein, is meant to encompass the items listed thereafter and equivalents thereof as well as additional items.

For purposes of clarity, certain terms are used herein as defined in the following table:

| | |
|---|---|
| Live sound | a mechanical vibration transmitted through a |
| | physical medium; however produced. |
| Sound source signal | a signal carrying information representing the |
| | mechanical vibration of a live sound. Signals may |
| | be carried by various modes in various media, such |
| | as current or voltage variations in electrical |
| | media, light intensities in optical media, and |
| | others. |
| Recorded sound | a sound source signal that has been fixed in a |
| | tangible medium, such as on a compact disk (CD) as |
| | a computer file (.mp3, .wav., .rm, etc.) on a hard |
| | disk, as a tape recording, and the like, for |
| | storage and subsequent playback. |

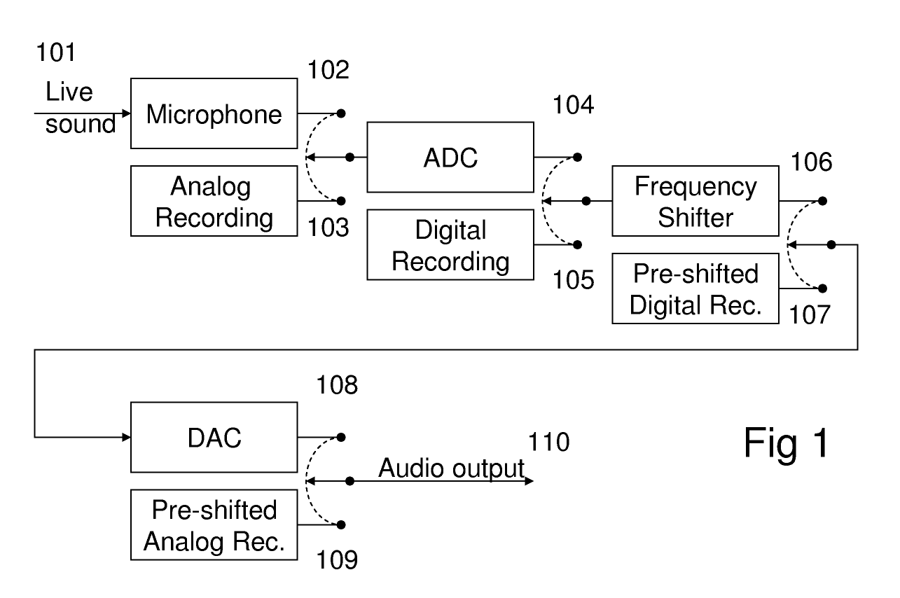

As shown in FIG. 1, microphone (102) receives live sound waves (101) from one or more live sources and converts the sound pressure vibrations into electrical impulses. These electrical impulses are then digitized by an Analog-to-Digital converter, or ADC (104). The digital sound samples are then transformed by a frequency shifter (106) described in more detail below. The transformed samples are then converted back into an analog representation by a Digital-to-Analog converter, or DAC (108) with the resulting output (110) delivered to the user's ears, for example by headphones or earphones. Embodiments of aspects of the invention also include recorded sound. These may be analog recordings (103), digital recordings (105), pre-shifted digital recordings (107) or pre-shifted analog recordings (109). In the case of analog recordings, the input source can be selected at the input of the ADC between the analog recordings and the microphone. In the case of digital recordings, the input source can be selected at the input to the frequency shifter between the ADC output and the digital recording. In the case of pre-shifted digital recordings, the input source can be selected between the output of the frequency shifter and the pre-shifted digital recordings. And in the case of pre-shifted analog recordings, the input source can be selected between the output of the DAC and the pre-shifted analog recording.

According to some embodiments of the invention, the recorded sound (103, 105 or 107) to be played may be selected and/or stored in a device such as described in U.S. patent application Ser. No. 10/903,658, filed Jul. 30, 2004, pending and incorporated herein by reference. Advantageously, the device of U.S. patent application Ser. No. 10/903,658 may be combined with the other elements described herein, so that a recorded sound of a bird or the like is identified and played alternately through the inventive technology with the live sound, permitting the user to confirm the selection even when the user cannot naturally hear the frequencies of the live sound adequately.

Advantageously, according to the illustrative embodiment, recorded sound including analog recordings (103) and digital recordings (105) which have not been pre-shifted undergo processing nearly identical to that performed on live sound received through microphone (102).

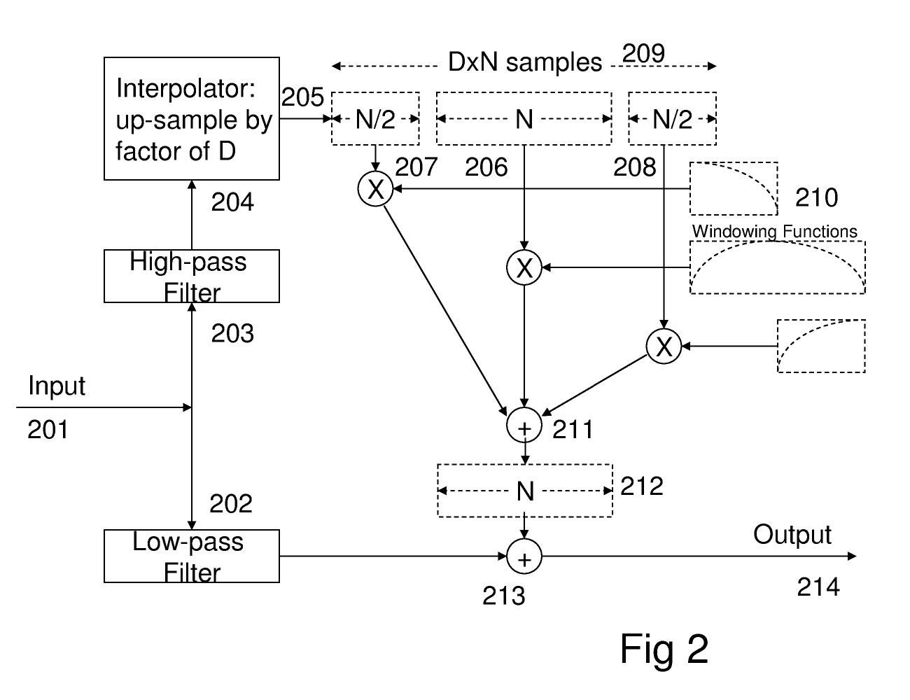

FIG. 2 illustrates the frequency shifter in more detail. The input signal (201) is split into two paths, one sent to a low-pass filter (202) while the other is sent to a high-pass filter (203). The cut-off frequency of these two filters is typically the same value such that high-frequencies beyond the range of hearing are passed by the high-pass filter while frequencies within the range of hearing are passed by the low-pass filter. This enables the invention to shift only those high frequencies that could not have been heard easily otherwise while preserving sounds that are more easily heard. For example, human speech is typically not shifted so that it doesn't sound unfamiliar to the user. A cut-off frequency of between 3-4 KHz works reasonably well because this represents the upper range of human speech.

Frequency shifting is performed by dividing frequencies by a factor D, where D is typically 2, 3, or 4. For example, the Blackpoll Warbler song in the 8-10 KHz range could be shifted to the 4-5 KHz range if divided by 2, the 2.7-3.3 KHz range if divided by 3, or the 2-2.5 KHz range if divided by 4. Different values of D may be appropriate depending on the frequency of the source and the severity of the high frequency hearing loss. In some embodiments, the value of D is fixed. In others, it may be configured by the user.

The output of the high-pass filter is up-sampled by a factor of D times using an interpolation filter (204). The interpolation filter will typically incorporate a low-pass anti-aliasing filter. The high-pass filter (203) may also be implemented as part of the interpolation filter (204). The output of the interpolation filter (205) contains D samples for every input sample.

Consider a block of N input samples. The interpolator will generate D×N output samples (209) for each block of N input samples. This is analogous to making a short recording with a tape recorder running at D times normal speed. If such a recording is played back at normal speed, it will sound slowed down, with frequencies divided by a factor of D. Thus, if N sequential samples are taken from the D×N interpolated samples, the frequencies in the sample will be divided by D. However, (D−1)×N/2 samples are also discarded from the input. The value of N should be set large enough to accommodate the resolution of low frequency outputs and yet small enough that the loss of information will not be noticed.

The middle N samples (206) of the D×N samples (209) are chosen as output representing the frequency shifted signal. These samples are combined (211) with the first N/2 (207) and the last N/2 (208) samples using windowing functions (210) to produce a block of N output samples (212). The windowing and combining removes phase and amplitude discontinuities between sample blocks.

The frequency shifted high-frequency samples (212) are combined (213) with the unmodified low-frequency samples from the low-pass filter (202) to produce the final frequency shifted output (214).

An alternative implementation of the frequency shifter can be implemented by performing a series of Discrete Fourier Transforms (DFTs) on the input samples, manipulating the results of the DFT in the frequency domain to implement the desired frequency shifting, and restoring the time domain signal by performing an Inverse Discrete Fourier Transform (IDFT) on the manipulated data. The DFTs and IDFTs can be performed using overlapped windows to smooth out phase and amplitude discontinuities. Any other suitable frequency or pitch shifting technology can be used in the alternative.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A method for listing to sound sources comprising:
receiving a first sound source signal from a microphone exposed to a live sound source;
receiving a second sound source signal from a recorded sound source;
selectively processing the received first sound source signal or second sound source signal through a pitch shifter which produces an output having sound frequencies in a desire range.

2. A method for listing to sound sources wherein selectively processing shifts the first sound source signal and the second sound source signal essentially identically.
